(19) United States
(12) Patent Application Publication
(10) Pub. No.: US 2014/0028681 A1
(43) Pub. Date: Jan. 30, 2014

(54) ELECTRONIC APPARATUS AND POWER CONSUMPTION DISPLAY METHOD

(71) Applicant: KABUSHIKI KAISHA TOSHIBA, TOKYO (JP)

(72) Inventor: Noriyuki Hirayama, Fuchu-shi (JP)

(73) Assignee: KABUSHIKI KAISHA TOSHIBA, TOKYO (JP)

(21) Appl. No.: 13/773,211

(22) Filed: Feb. 21, 2013

(30) Foreign Application Priority Data
Jul. 25, 2012 (JP) 2012-164944

(51) Int. Cl. G01R 31/36

(52) U.S. Cl. CPC G01R 31/3606
USPC 345/440; 702/63

(57) ABSTRACT

According to one embodiment, an electronic apparatus includes a log receiver and a log display processor. The log receiver receives battery information items and one or more driving information items from a server, the battery information items including first information for first state of charge of a battery in an electric vehicle and second information for second state of charge of the battery, the driving information items including information indicating a use of the vehicle from a timing at which the second information is uploaded to the server to a timing at which the first information is uploaded to the server. The log display processor displays states of charge of the battery and the driving information items laid out in association with the states.

### CROSS-REFERENCE TO RELATED APPLICATIONS

This application is based upon and claims the benefit of priority from Japanese Patent Application No. 2012-164944, filed Jul. 25, 2012, the entire contents of which are incorporated herein by reference.

### FIELD

Embodiments described herein relate generally to an electronic apparatus which manages the power consumption of an electric vehicle, and a power consumption display method applied to the apparatus.

### BACKGROUND

Recently, an electric vehicle (EV), hybrid electric vehicle (HEV), and plug-in HEV (PHEV) are becoming popular. These electric vehicles have the feature that they are energy-efficient, low-emission vehicles, so demands for these vehicles are increasing as people are taking a growing interest on energy saving and the influence on environments. An electric vehicle is equipped with a rechargeable battery such as a lithium-ion battery, and driven by using electric power supplied from the charged rechargeable battery.

A method of displaying the fuel efficiency (fuel consumption) of a vehicle driven by using gasoline or diesel oil has been proposed. This method displays the fuel efficiency by demanding the user (e.g., the driver) of a vehicle to input information on the mileage and refueled amount when the user refuels the vehicle. This allows the user to confirm the vehicle's fuel efficiency.

In this fuel efficiency display method, however, it is difficult to grasp what has caused the fluctuation in fuel efficiency. Also, when using this fuel efficiency display method, it is difficult for the user of an electric vehicle described above to confirm what has caused the fluctuation in power consumption of the EV.

### BRIEF DESCRIPTION OF THE DRAWINGS

A general architecture that implements the various features of the embodiments will now be described with reference to the drawings. The drawings and the associated descriptions are provided to illustrate the embodiments and not to limit the scope of the invention.

FIG. 1 is an exemplary conceptual view for explaining a power consumption management system including an electronic apparatus according to an embodiment.

FIG. 2 is an exemplary perspective view showing the external appearance of the electronic apparatus of the embodiment.

FIG. 3 is an exemplary block diagram showing the system configuration of the electronic apparatus of the embodiment.

FIG. 4 is an exemplary block diagram for explaining the functional configuration of an apparatus management application executed by the electronic apparatus of the embodiment.

FIG. 5 is an exemplary view showing the arrangement of an ID management table stored in a server in the power consumption management system shown in FIG. 1.

FIG. 6 is an exemplary view showing the arrangement of a battery information management table stored in the server in the power consumption management system shown in FIG. 1.

FIG. 7 is an exemplary view showing an example of a driving information input screen displayed by the electronic apparatus of the embodiment.

FIG. 8 is an exemplary view showing the arrangement of a driving information management table stored in the server in the power consumption management system shown in FIG. 1.

FIG. 9 is an exemplary view showing a battery information screen displayed by the electronic apparatus of the embodiment.

FIG. 10 is an exemplary view showing the arrangement of a log information table used by the electronic apparatus of the embodiment.

FIG. 11 is an exemplary view showing a log screen displayed by the electronic apparatus of the embodiment.

FIG. 12 is an exemplary flowchart showing an example of the procedure of a power consumption management process executed by the power consumption management system shown in FIG. 1.

FIG. 13 is an exemplary flowchart showing an example of the procedure of a log display process executed by the electronic apparatus of the embodiment.

FIG. 14 is an exemplary view for explaining another configuration of the power consumption management system shown in FIG. 1.

### DETAILED DESCRIPTION

Various embodiments will be described hereinafter with reference to the accompanying drawings.

In general, according to one embodiment, an electronic apparatus includes a difference information receiver, an input processor, a driving information transmitter, a log receiver, and a log display processor. The difference information receiver is configured to receive difference information indicative of a difference between a first state of charge of a battery in an electric vehicle and a second state of charge of the battery from a server, the difference being obtained based on first information for the first state and second information for the second state, the first information being uploaded from the electric vehicle, the second information being uploaded immediately before the first information from the electric vehicle. The input processor is configured to receive, if the difference information indicates that a decrease in state of charge is equal to or larger than a threshold, an input including a use of the electric vehicle from a timing at which the second information is uploaded to a timing at which the first information is uploaded. The driving information transmitter is configured to transmit driving information to the server, the driving information being generated based on the input. The log receiver is configured to receive a plurality of battery information items and one or more driving information items from the server, the battery information items including the first information and the second information, the one or more driving information including the transmitted driving information. The log display processor is configured to display a log screen including states of charge of the battery based on the battery information items, and the one or more driving information items laid out in association with the states of charge.

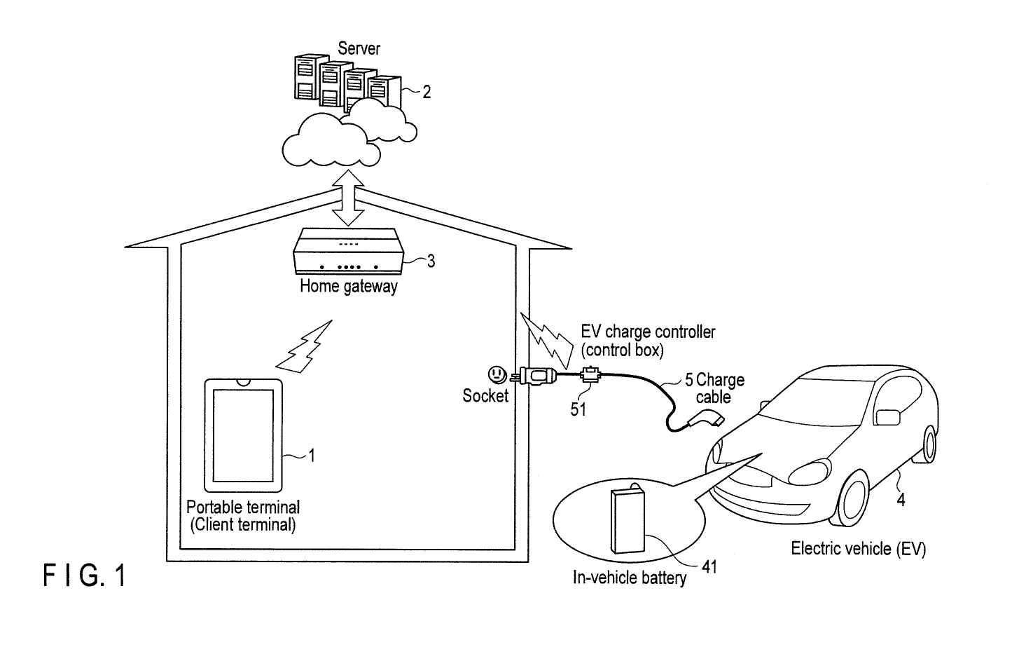

First, a power consumption management system including an electronic apparatus according to an embodiment will be explained below with reference to FIG. 1. This power consumption management system manages the power consumption of an electric vehicle (to be also referred to as an EV hereinafter) 4. More specifically, the power consumption management system manages the fluctuation of state of charge of an in-vehicle battery 41 of the EV 4, and the cause of the fluctuation.

The power consumption management system includes an electronic apparatus (client terminal) 1 according to this embodiment, a server 2, a home gateway 3, the EV 4, and a charge cable 5. The client terminal 1, the server 2, and an EV charge controller 51 attached to the charge cable 5 communicate with each other via the home gateway 3. The in-vehicle battery 41 of the EV 4 is charged through the charge cable 5 connected to a socket.

The client terminal 1 can be implemented as a mobile communication terminal such as a tablet-type personal computer (tablet computer), smartphone, cell phone, or PDA. The client terminal 1 may also be implemented as any of various personal computers other than a tablet PC, a car navigation system, or a built-in system of any of various electronic apparatuses. In the following explanation, it is assumed that the client terminal 1 is implemented as a tablet computer.

The server 2 can be implemented as, e.g., a server computer. The server 2 stores information on the in-vehicle battery 41 of the EV 4.

The EV 4 includes an electric vehicle (EV), hybrid electric vehicle (HEV), and plug-in hybrid electric vehicle (PHEV). The EV 4 is equipped with the in-vehicle battery 41, and driven by using electric power supplied from the in-vehicle battery 41. The in-vehicle battery 41 is, e.g., a rechargeable battery such as a lithium-ion battery. The in-vehicle battery 41 is charged through the charge cable 5 connected to, e.g., an EV charge socket. The EV 4 also includes a wired or wireless communication device (communication interface).

The charge cable 5 is a power cable for connecting the socket and EV 4. Accordingly, when one end of the charge cable 5 is connected to the socket and its other end is connected to the EV 4, the in-vehicle battery 41 is charged by using electric power supplied through the charge cable 5. The charge cable 5 includes the EV charge controller (control box) 51 having a function of communicating with an external apparatus. The charge cable 5 also functions as a communication cable for performing wired communication between the EV charge controller 51 and EV 4. That is, the EV charge controller 51 and EV 4 can communicate with each other through the charge cable 5.

The EV charge controller 51 receives information about the in-vehicle battery 41 (e.g., the battery capacity of the in-vehicle battery 41 when it is fully charged, and the present residual battery capacity of the in-vehicle battery 41) from the EV 4, by communication (wired communication) based on, e.g., the IEC61851 standards. Then, the EV charge controller 51 uploads the received information on the in-vehicle battery 41 to the server 2 via the home gateway 3, by wireless communication (e.g., wireless LAN communication) based on, e.g., the ECHONET Lite standards.

The home gateway (to be also referred to as a gateway hereinafter) 3 connects networks so as to transmit information between networks using different communication protocols. The home gateway 3 converts information to be transmitted between, e.g., the client terminal 1, server 2, and EV charge controller 51, into a form suited to a protocol used on the receiving side, and then transmits the converted information. The home gateway 3 includes, e.g., a wireless LAN communication module, and functions as a wireless LAN access point. Accordingly, the home gateway 3 executes wireless LAN communication between the EV charge controller 51 and client terminal 1. The home gateway 3 also has a function of communicating with the server 2 across the Internet.

Note that in order to simplify the explanation, it is assumed that one user uses one electric vehicle in the following description. However, this embodiment is of course also applicable when, e.g., one user uses a plurality of electric vehicles, or a plurality of users share one electric vehicle.

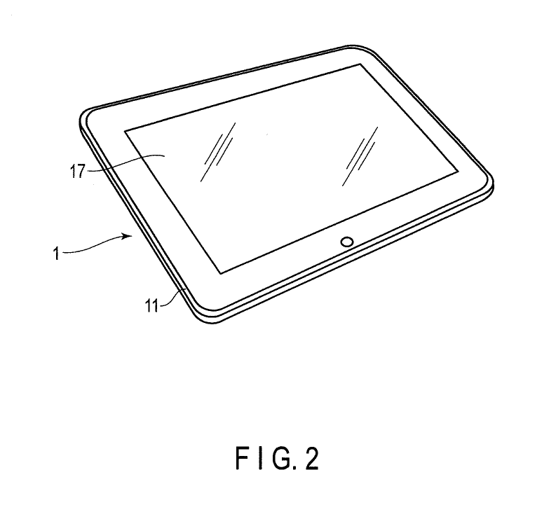

FIG. 2 is an exemplary perspective view illustrating an external appearance of the client terminal 1. As shown in FIG. 2, the client terminal 1 includes a main body 11 and a touch-screen display 17. The touch-screen display 17 is attached such that the touch-screen display 17 is laid over the top surface of the main body 11.

The main body 11 has a thin box-shaped housing. A flat-panel display and a sensor are built into the touch-screen display 17. The sensor is configured to detect a touch position of a pen or a finger on the screen of the flat-panel display. The flat-panel display may be, for instance, a liquid crystal display (LCD). As the sensor, for example, use may be made of a capacitance-type touch panel, or an electromagnetic induction-type digitizer. The touch panel (or the digitizer) is provided in a manner to cover the screen of the flat-panel display.

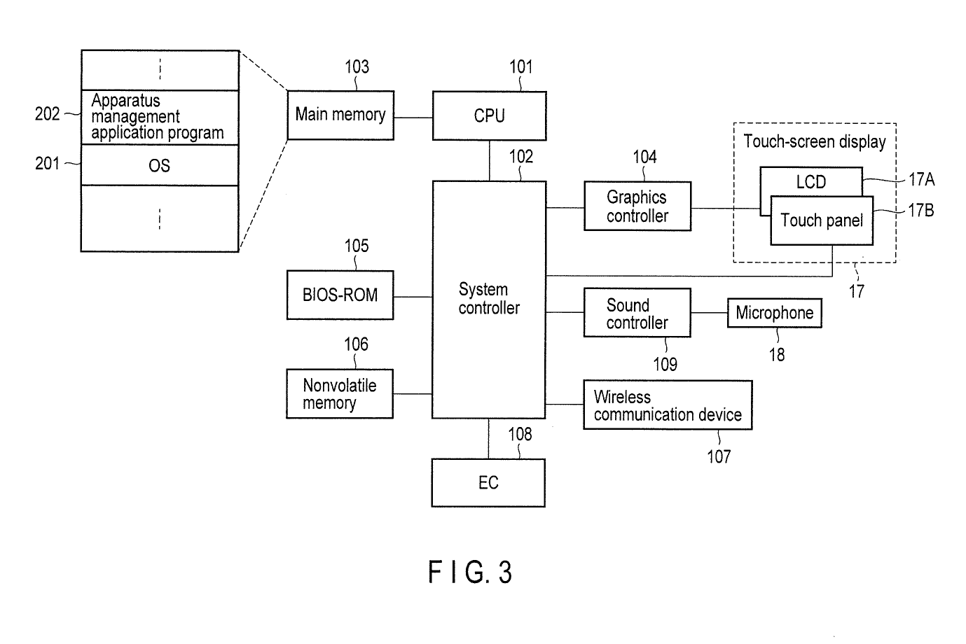

FIG. 3 is a view showing the system configuration of the client terminal 1.

As shown in FIG. 3, the client terminal 1 includes a CPU 101, a system controller 102, a main memory 103, a graphics controller 104, a BIOS-ROM 105, a nonvolatile memory 106, a wireless communication device 107, an embedded controller (EC) 108, a sound controller 109, a touch screen display 17, and a microphone 18.

The CPU 101 is a processor for controlling the operations of various modules in the client terminal 1. The CPU 101 executes various kinds of software loaded into the main memory 103 from the nonvolatile memory 106 as a storage device. These pieces of software include an operating system (OS) 201 and various application programs. The application programs include an apparatus management application program 202. The apparatus management application program 202 has, e.g., a battery information uploading function of uploading information (battery information) on the in-vehicle battery 41 to the server 2, a driving information uploading function of uploading, to the server 2, driving information (operation information) that corresponds to the battery information and indicates the use of the EV 4, and a log displaying function of displaying the logs of the battery information and driving information.

In the battery information uploading function, the apparatus management application program 202 requests the EV charge controller 51 to upload the battery information on the in-vehicle battery 41 to the server 2. Note that in this battery information uploading function, the client terminal 1 may also receive the battery information transmitted from the EV charge controller 51, and upload the received battery information to the server 2. This battery information includes, e.g., the ID of the in-vehicle battery 41, the capacity (maximum battery capacity) when the in-vehicle battery 41 is fully charged, and the present residual amount (present residual battery capacity) of the in-vehicle battery 41. In other words, the battery information includes the ID of the in-vehicle battery 41 and information for the state of charge of the in-vehicle battery 41.

In the driving information uploading function, the apparatus management application program 202 prompts the user to input the driving information indicative of the use of the EV 4 from the timing at which the battery information is uploaded last time to the timing at which the battery information is uploaded this time, and then uploads the input driving information to the server 2. The driving information includes a description related to the cause of the fluctuation in residual amount of the in-vehicle battery 41. For example, the driving information includes information that explains the behavior of the user when the user used the EV 4, an event performed when the EV 4 was used, the driver who drove the EV 4, and a fellow passenger of the EV 4. That is, this driving information gives the corresponding battery information an objective explanation which the user can readily understand.

In the log displaying function, the apparatus management application program 202 downloads the battery information and driving information in a predetermined period from the server 2, and displays a log screen using the battery information and driving information. On the log screen, a graph indicative of the transition of the state of charge of the in-vehicle battery 41, and the driving information are displayed in association with each other. The user can confirm the fluctuation in state of charge and the cause of the fluctuation by watching the log screen.

The CPU 101 also executes a basic input/output system (BIOS) stored in the BIOS-ROM 105. The BIOS is a program for hardware control.

The system controller 102 is a device that connects the local bus of the CPU 101 and various components. The system controller 102 also incorporates a memory controller that controls access to the main memory 103. In addition, the system controller 102 has a function of communicating with the graphics controller 104 and sound controller 109 via, e.g., a serial bus complying with the PCI EXPRESS standards.

The graphics controller 104 is a display controller that controls an LCD 17A used as a monitor display of the client terminal 1. A display signal generated by the graphics controller 104 is supplied to the LCD 17A. The LCD 17A displays an image based on this display signal. A touch panel 17B is placed on the LCD 17A. The touch panel 17B is, e.g., a capacitance-type pointing device for inputting on the screen of the LCD 17A. The touch panel 17B detects a finger contact position on the screen, the movement of the contact position, and the like.

The sound controller 109 is a sound source device. The sound controller 109 saves (records) a sound input by using the microphone 18 as audio data, and outputs audio data to be played back to a speaker.

The wireless communication device 107 is configured to execute wireless communication (wireless LAN communication) based on the IEEE802.11 standards, or wireless communication such as 3G mobile communication. The EC 108 is a one-chip microcomputer including an embedded controller for power management. The EC 108 has a function of turning on or off the client terminal 1 in accordance with an operation on a power button by the user.

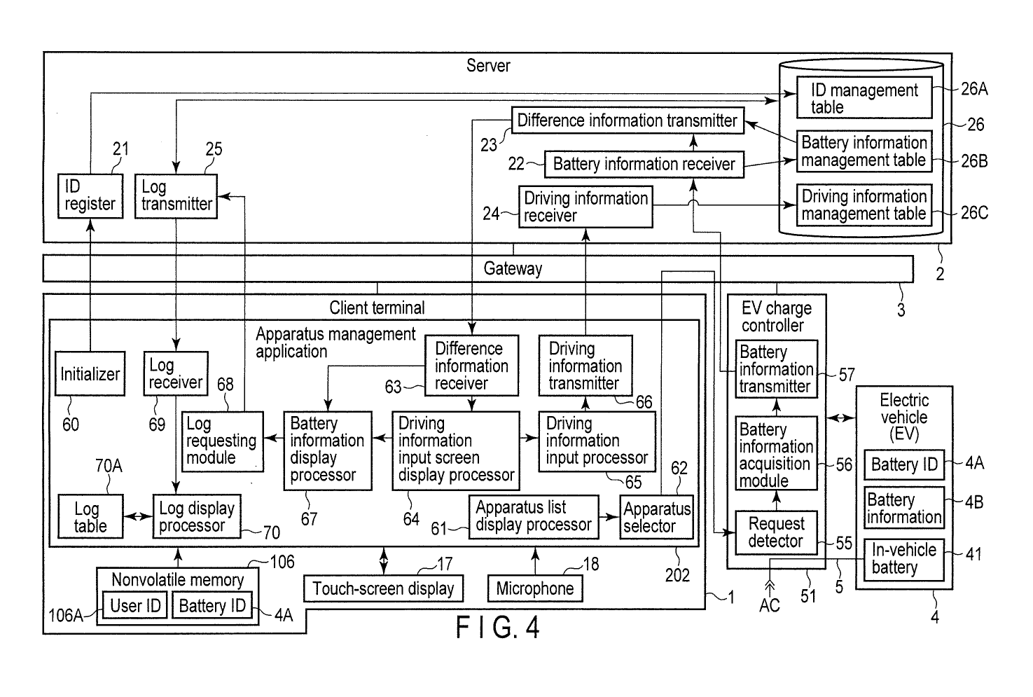

Next, the functional configuration of the apparatus management application 202 executed by the client terminal 1 and the functional configuration of the server 2 and EV charge controller 51 that operate in cooperation with the apparatus management application 202 will be explained with reference to FIG. 4. Note that in the following explanation, it is assumed that the EV 4 and the power supply socket are connected by the charge cable 5 (e.g., the user has come home by the EV 4 and connected the socket of the house and the EV 4 by using the charge cable 5).

The apparatus management application 202 includes an initializer 60, an apparatus list display processor 61, an apparatus selector 62, a difference information receiver 63, a driving information input screen display processor 64, a driving information input processor 65, a driving information transmitter 66, a battery information display processor 67, a log requesting module 68, a log receiver 69, and a log display processor 70.

The server 2 includes an ID register 21, a battery information receiver 22, a difference information transmitter 23, a driving information receiver 24, and a log transmitter 25. The EV charge controller 51 includes a request detector 55, a battery information acquisition module 56, and a battery information transmitter 57.

Processing performed by the apparatus management application 202 can be divided into (1) an initialization phase, (2) an upload phase, and (3) a log presentation phase.

In the initialization phase, a pair of identification information (a battery ID 4A) of the in-vehicle battery 41 of the EV 4 and identification information (a user ID 106A) of the user of the EV 4 are registered in the server 2. In the upload phase, battery information on the in-vehicle battery 41 is uploaded to the server 2, and driving information corresponding to the battery information is then uploaded to the server 2. In the log presentation phase, the battery information and driving information are downloaded from the server 2, and a log screen based on the downloaded battery information and driving information is displayed. The operations in these three phases will be explained below.

First, the operation in the initialization phase will be explained.

To register the identification information of the user of the EV 4 and the identification information of the in-vehicle battery 41 of the EV 4 in the server 2, the initializer 60 of the apparatus management application 202 reads the user ID 106A and battery ID 4A from the nonvolatile memory 106, and then transmits the read user ID 106A and battery ID 4A to the server 2. The battery ID 4A is stored in, e.g., a nonvolatile memory of the EV 4, and received from the EV 4 via the EV charge controller 51 or the like. Note that the user ID 106A and battery ID 4A may also be input by the user by using, e.g., a software keyboard displayed on the touch screen display 17. The initializer 60 registers the user ID 106A and battery ID 4A in the server 2 when, e.g., the apparatus management application 202 is initially activated.

The ID register 21 of the server 2 registers the user ID 106A and battery ID 4 transmitted from the initializer 60 in an ID management table 26A. More specifically, the ID register 21 generates an entry including the user ID 106A and battery ID 4A, and then adds the generated entry to the ID management table 26A.

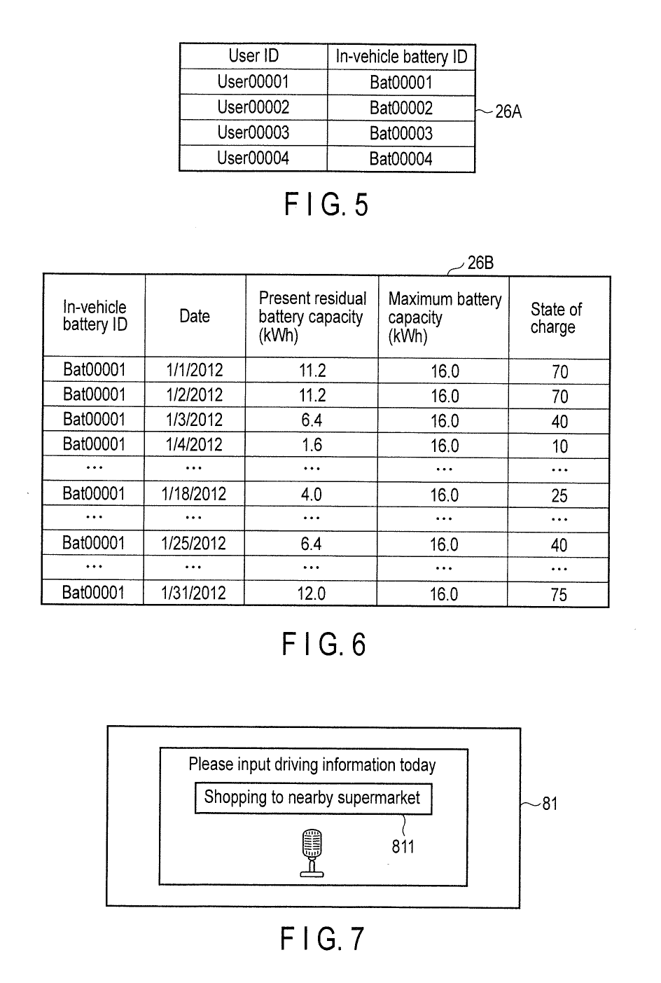

FIG. 5 shows an arrangement example of the ID management table 26A stored in the server 2. The ID management table 26A includes a plurality of entries corresponding to a plurality of users. Each entry includes the user ID and in-vehicle battery ID.

In an entry corresponding to a given user, “user ID” indicates identification information given to the user. “In-vehicle battery ID” indicates identification information given to an in-vehicle battery of an EV used by the user.

By referring to the ID management table 26A, it is known that, e.g., an EV used by a user having user ID “User00001” incorporates a battery having in-vehicle battery ID “Bat00001”. It is also known that, e.g., a user having user ID “User00002” uses an electric vehicle incorporating a battery having in-vehicle battery ID “Bat00002”.

Next, the upload phase will be explained.

The apparatus list display processor 61 of the client terminal 1 displays a list (to be referred to as an apparatus list hereinafter) of various consumer apparatuses to be managed by the apparatus management application 202. These consumer apparatuses include the EV 4, a refrigerator, and an air conditioner. The apparatus list display processor 61 displays the apparatus list when, e.g., the apparatus management application 202 is activated, or the user inputs an operation of requesting the display of the apparatus list. The user performs an operation of selecting a management target apparatus from the apparatus list by using, e.g., the touch screen display 17.

The apparatus selector 62 detects the management target apparatus selected from the apparatus list. Then, the apparatus selector 62 executes predetermined processing corresponding to the selected apparatus. When the EV 4 is selected from the apparatus list, the apparatus selector 62 requests the EV charge controller 51 to upload the battery information 4B of the EV 4 to the server 2.

The request detector 55 of the EV charge controller 51 detects the upload request from the apparatus selector 62. Then, the request detector 55 notifies the battery information acquisition module 56 of the detection of the upload request.

The battery information acquisition module 56 acquires (receives) the battery ID 4A and battery information 4B from the EV 4 by communicating with the EV 4 through the charge cable 5. The battery ID 4A is the identification information given to the in-vehicle battery 41 of the EV 4. The battery information 4B includes information on the state of charge of the in-vehicle battery 41. The battery information 4B includes information indicative of, e.g., the power amount (maximum battery capacity) when the in-vehicle battery 41 is fully charged, and the present residual power amount (residual battery capacity) of the in-vehicle battery 41. The battery information 4B may include information indicative of the state of charge of the in-vehicle battery 41. The battery information 4B may further include information indicative of the traveling route and mileage of the EV 4 obtained by using a GPS receiver or the like. The battery information acquisition module 56 outputs the acquired battery ID 4A and battery information 4B to the battery information transmitter 57.

The battery information transmitter 57 transmits (uploads), to the server 2, the battery ID 4A and battery information 4B output from the battery information acquisition module 56.

The battery information receiver 22 of the server 2 receives the battery ID 4A and battery information 4B transmitted from the battery information transmitter 57. The battery information receiver 22 stores the received battery ID 4A and battery information 4B in a battery information management table 26B. More specifically, the battery information receiver 22 first calculates the state of charge of the in-vehicle battery 41 based on the maximum battery capacity and present residual battery capacity indicated in the battery information 4B. For example, the battery information receiver 22 calculates the state of charge by

State of charge=present residual battery capacity/maximum battery capacity×100 [%].

Note that if the battery information 4B includes the state of charge, the battery information receiver 22 directly uses the state of charge without performing the above-described calculation. The battery information receiver 22 generates an entry including, e.g., the battery ID 4A, date (or date and time), present residual battery capacity, maximum battery capacity, and state of charge, and then adds the generated entry to the battery information management table 26B. The battery information receiver 22 outputs the received battery ID 4A to the difference information transmitter 23.

FIG. 6 shows an arrangement example of the battery information management table 26B stored in the server 2. The battery information management table 26B includes a plurality of entries corresponding to a plurality of battery information items. Each entry includes, e.g., the in-vehicle battery ID, date, present residual battery capacity, maximum battery capacity, and state of charge.

In an entry corresponding to given battery information, “in-vehicle battery ID” indicates the ID of an in-vehicle battery corresponding to the in-vehicle battery information. “Date” indicates the date on which the battery information is received (generated). “Present residual battery capacity” indicates the residual amount (residual battery capacity) of the in-vehicle battery having the ID indicated by “in-vehicle battery ID” on the day indicated by “date”. “Maximum battery capacity” indicates the battery capacity (maximum battery capacity) when the in-vehicle battery is fully charged. “State of charge” indicates a ratio (%) of the present residual battery capacity to the maximum battery capacity.

By referring to the battery information management table 26B, it is possible to find, e.g., the state of charge of a given in-vehicle battery on a given date. In the example shown in FIG. 6, it is possible to find that, e.g., the residual battery capacity of the in-vehicle battery 41 having in-vehicle battery ID “Bat00001” is 11.2 kWh, the maximum battery capacity of the in-vehicle battery 41 is 16.0 kWh, and the state of charge of the in-vehicle battery 41 is 70% on “Jan. 1, 2012”. Note that the battery information 4B of the in-vehicle battery 41 may be uploaded a plurality of times on the same day. In this case, an entry including, e.g., the in-vehicle battery ID, date/time, present residual battery capacity, maximum battery capacity, and state of charge is added to the battery information management table 26B by using the battery information 4B.

Then, among entries including the battery ID 4A output from the battery information receiver 22, the difference information transmitter 23 of the server 2 reads two entries having the latest dates from the battery information management table 26B by using the battery ID 4A. That is, from the entries including the battery ID 4A in the battery information management table 26B, the difference information transmitter 23 reads an entry added this time (first information uploaded this time) by the battery information receiver 22, and an entry added last time (e.g., yesterday) (second information uploaded last time) by the battery information receiver 22.

Subsequently, the difference information transmitter 23 calculates the difference between a last state of charge (second state of charge) and a present state of charge (first state of charge) by using the two read entries. For example, when the last state of charge is 70% and the present state of charge is 30%, the difference of state of charge is 40%, indicating that the state of charge has decreased by 40%. Also, when the last state of charge is 30% and the present state of charge is 70%, the difference of state of charge is −40%, indicating that the state of charge has increased by 40%. The difference information transmitter 23 transmits difference information on the difference between the first and second states of charge to the client terminal 1. This difference information includes, e.g., the calculated difference of state of charge, and the maximum battery capacity, residual battery capacity, and state of charge in the entry added this time (i.e., the entry having the latest date).

The difference information receiver 63 of the client terminal 1 receives the difference information transmitted from the difference information transmitter 23. As described above, this difference information includes, e.g., the difference of state of charge, maximum battery capacity, residual battery capacity, and state of charge. The difference information receiver 63 determines whether the received difference of state of charge is equal to or larger than a threshold (e.g., 15%). If the difference of state of charge is equal to or larger than the threshold (i.e., if the decrease in state of charge of the in-vehicle battery 41 is equal to or larger than the threshold), the difference information receiver 63 requests the driving information input screen display processor 64 to display the driving information input screen. On the other hand, if the difference of state of charge is smaller than the threshold (i.e., if the decrease in state of charge is smaller than the threshold, or if the state of charge has increased), the difference information receiver 63 requests the battery information display processor 67 to display the battery information screen.

Note that in this embodiment, the method by which the server 2 calculates the difference and transmits the difference information obtained by the calculation to the client terminal 1 has mainly been explained. However, the server 2 need not calculate the difference. In this case, the server 2 transmits the battery information as information about the difference information to the client terminal 1, and then the client terminal 1 (apparatus management application program 202) calculates the difference of state of charge by using the battery information. The server 2 may also transmit, to the client terminal 1, latest battery information which has been uploaded as information about the difference information. The client terminal 1 receives and stores the battery information, and, when receiving latest battery information next, calculates the difference based on the stored battery information and the received latest battery information.

The driving information input screen display processor 64 displays the driving information input screen in accordance with the request from the difference information receiver 63. The driving information input screen is a screen for prompting the user to input (externally input) driving information indicating the use of the EV 4 from the timing at which the battery information 4B is uploaded last time to the timing at which the battery information 4B is uploaded this time.

FIG. 7 shows an example of a driving information input screen 81 displayed by the driving information input screen display processor 64. By using the driving information input screen 81, the user inputs driving information corresponding to the battery information 4B uploaded to the server 2. As described above, the driving information input screen 81 is displayed when the decrease in state of charge of the in-vehicle battery 41 is equal to or larger than the threshold, based on the uploaded battery information 4B and the battery information 4B uploaded immediately before that (e.g., yesterday). The driving information indicates the use of the EV 4, which corresponds to the uploaded battery information 4B. More specifically, the driving information indicates, e.g., the behavior, destination, event, fellow passenger, and driver when the EV 4 was used.

The driving information input screen 81 includes a driving information input area 811 for inputting driving information. The user selects (taps) the driving information input area 811 by using the touch screen display 17 or the like, and then inputs a character string (text) as driving information in the driving information input area 811 by using a software keyboard displayed in response to the selection (tapping). The user may also input driving information by inputting a voice by using the microphone 18. As the driving information, a description readily understandable by the user is input. More specifically, the driving information includes information of a place name such as “Lake Sagami”, information of a use such as “shopping to nearby supermarket”, or information of a driver (or fellow passenger) such as “wife visited friend's house”. By using the driving information input screen 81, therefore, the user can input driving information corresponding to the battery information 4B uploaded to the server computer 2, and including a description readily understandable by the user.

The driving information input processor 65 receives (accepts) an input using the driving information input screen 81, and then processes the input. More specifically, the driving information input processor 65 receives input performed on the driving information input screen 81 by using a keyboard (software keyboard). When a character string is input in the driving information input area 811 by using the keyboard, the driving information input processor 65 detects the input character string (text) and generates driving information including the detected character string. Also, the driving information input processor 65 receives an input to the microphone 18 while the driving information input screen 81 is displayed. In this case, when a voice is input by using the microphone 18, the driving information input processor 65 recognizes a character string corresponding to the input voice (voice data) by analyzing the voice, and generates driving information including the recognized character string. When voice input is performed, the driving information input processor 65 displays the recognized character string in the driving information input area 811. The driving information input processor 65 outputs the generated driving information to the driving information transmitter 66.

Then, the driving information transmitter 66 transmits (uploads) the user ID 106A and the driving information output from the driving information input processor 65 to the server 2 (the driving information receiver 24).

As described above, if the difference of state of charge indicates that the decrease in state of charge is equal to or larger than the threshold, the difference information receiver 63, the driving information input screen display processor 64, the driving information input processor 65, and the driving information transmitter 66 can transmit, to the server 2, the driving information indicating the use of the EV 4 from the timing at which the battery information (second information) is uploaded last time to the timing at which the battery information (first information) is uploaded this time.

The driving information receiver 24 of the server 2 receives the user ID 106A and driving information transmitted from the driving information transmitter 66. The driving information receiver 24 stores the received user ID 106A and driving information in a driving information management table 26C. More specifically, the driving information receiver 24 generates an entry including, e.g., the user ID, date (or date and time), and driving information, and then adds the generated entry to the driving information management table 26C.

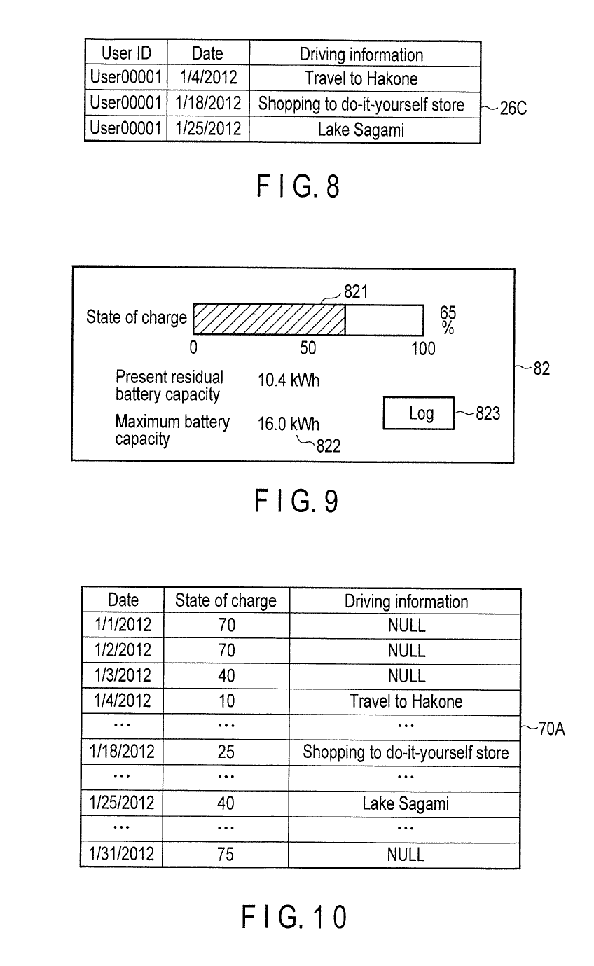

FIG. 8 shows an arrangement example of the driving information management table 26C stored in the server 2. The driving information management table 26C includes a plurality of entries corresponding to a plurality of driving information items. Each entry includes, e.g., the user ID, date, and driving information. In an entry corresponding to given driving information, “user ID” indicates identification information given to a user having input the driving information. “Date” indicates the date (or date and time) on which the driving information is generated (received). “Driving information” indicates the description of the driving information.

By referring to the driving information management table 26C, it is known that the use of using the EV 4 on “Jan. 4, 2012” by a user having user ID “User00001” is “Travel to Hakone”.

Note that after the driving information is input by using the driving information input screen 81 (or after the driving information is transmitted to the server 2), the driving information input screen display processor 64 of the client terminal 1 stops displaying the driving information input screen 81. Then, the driving information input screen display processor 64 requests the battery information display processor 67 to display the battery information screen.

In response to the request from the difference information receiver 63 or the request from the driving information input screen display processor 64, the battery information display processor 67 displays the battery information screen. That is, if the difference of state of charge transmitted from the server 2 is smaller than the threshold (if the decrease in state of charge is smaller than the threshold), the battery information display processor 67 skips the display of the driving information input screen 81 and displays the battery information screen. If the difference of state of charge transmitted from the server 2 is equal to or larger than the threshold (if the decrease in state of charge is equal to or larger than the threshold), the battery information display processor 67 displays the battery information screen after the display of the driving information input screen 81 is complete. The battery information display processor 67 displays the battery information screen by using, e.g., the maximum battery capacity, residual battery capacity, and state of charge received by the difference information receiver 24.

FIG. 9 shows an example of the battery information screen 82 displayed by the battery information display processor 67. The battery information screen 82 includes a state of charge display area 821, a battery capacity display area 822, and a log button 823. In the state of charge display area 821, for example, the ratio of the present residual battery capacity to the maximum battery capacity (i.e., the state of charge), and a graph representing the ratio are displayed. In the battery capacity display area 822, the numerical values of the present residual battery capacity and maximum battery capacity are displayed. The log button 823 is a button for designating the display of the log screen.

The user can confirm the present state of charge of the in-vehicle battery 41 on the battery information screen 82. The user can also designate the display of the log screen showing the relationship between the fluctuation in state of charge and the driving information, by performing an operation of selecting (tapping) the log button 823.

The log presentation phase will now be explained.

The log requesting module 68 of the client terminal 1 determines whether it is requested to display the logs of the battery information and driving information of the EV 4. The log requesting module 68 determines that the display of the logs is requested if, e.g., the log button 823 on the above-described battery information screen 82 is selected.

When the display of the log is requested, the log requesting module 68 requests the server 2 (the log transmitter 25) to transmit the battery information and driving information of the EV 4 used by the user of the client terminal 1. This request includes the battery ID 4A and user ID 106A.

In response to the request from the log requesting module 68, the log transmitter 25 of the server 2 extracts entries associated with the EV 4 from the battery information management table 26B, and entries associated with the user from the driving information management table 26C. More specifically, based on the battery ID 4A transmitted from the log requesting module 68, the log transmitter 25 extracts entries (battery information entry) including the battery ID 4A from the battery information management table 26B. Note that the log transmitter 25 may also extract entries including the battery ID 4A and dates in a predetermined period (e.g., an immediately preceding month, this month, or this year). Also, based on the user ID 106A transmitted from the log requesting module 68, the log transmitter 25 extracts entries (driving information entry) including the user ID 106A from the driving information management table 26C. The log transmitter 25 may also extract entries including the user ID 106A and dates in a predetermined period (e.g., an immediately preceding month, this month, or this year) from the driving information management table 26C. The log transmitter 25 transmits the extracted battery information entries and driving information entries to the client terminal 1 (the log receiver 69).

The log receiver 69 of the client terminal 1 receives the battery information entries and driving information entries transmitted from the log transmitter 25. The log receiver 69 outputs the received battery information entries and driving information entries to the log display processor 70.

The log display processor 70 displays a log screen in which the state of charge of the in-vehicle battery 41 and the driving information are associated with each other, based on the battery information entries and driving information entries output from the log receiver 69. More specifically, the log display processor 70 generates a log table 70A by integrating the battery information entries and driving information entries output from the log receiver 69. The log display processor 70 integrates the battery information entries and driving information entries based on the date (or date and time), thereby generating the log table 70A indicating the correspondence between the state of charge of the in-vehicle battery 41 and the driving information on, e.g., a given date. By using the generated log table 70A, the log display processor 70 displays the log screen including a graph indicating the transition of the state of charge, and the driving information laid out in association with the graph.

FIG. 10 shows an arrangement example of the log table 70A generated by the log display processor 70. As described above, the log table 70A is generated by integrating, based on the date (or date and time), the entries of the battery information management table 26B and the entries of the driving information management table 26C downloaded from the server 2. The log table 70A includes a plurality of entries corresponding to a plurality of log information items. Each entry includes, e.g., the date, state of charge, and driving information. In an entry corresponding to given log information, “date” indicates the date corresponding to the log information. “State of charge” indicates the state of charge of the in-vehicle battery 41 of the EV 4 on a day indicated by “date”. “Driving information” indicates the use of the EV 4 on the day indicated by “date”. Note that “NULL” set in “driving information” indicates that there is no driving information on the day.

By referring to the log table 70A, it is known that, e.g., the state of charge of the in-vehicle battery 41 was 10% on “Jan. 4, 2012”, and the use of the EV 4 on that day was “travel to Hakone”.

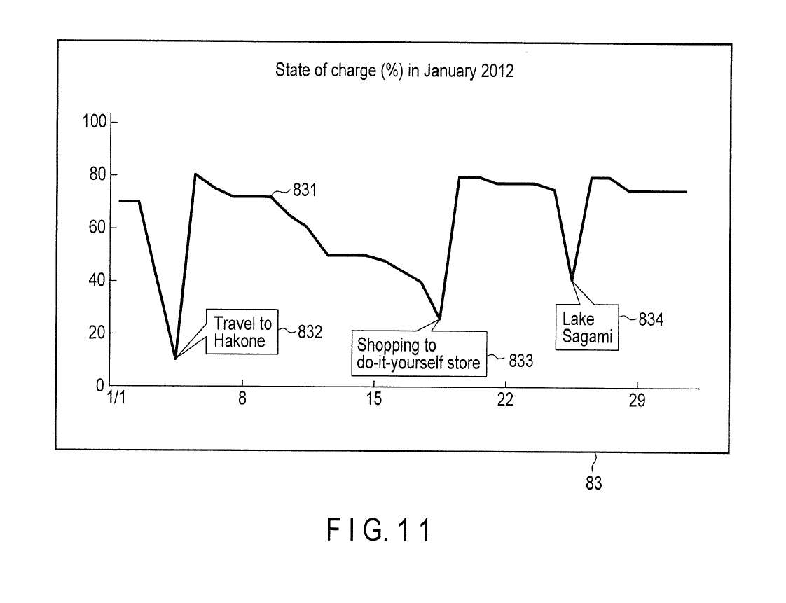

Also, FIG. 11 shows an example of the log screen 83 displayed by the log display processor 70. Based on the log table 70A, the log screen 83 displays a line graph 831 in which the date is plotted on the horizontal axis and the state of charge is plotted on the vertical axis. In addition, based on the log table 70A, balloons 832, 833, and 834 describing driving information are displayed in portions corresponding to days having the driving information (e.g., portions corresponding to days on which the decrease in state of charge was equal to or larger than the threshold). The start points of the balloons 832, 833, and 834 are set at, e.g., the respective corresponding values of the state of charge on the graph 831. Note that the log screen 83 is not limited to the state of charge graph 831 and the balloons 832, 833, and 834 describing the driving information, and need only include descriptions indicating the relationship between the transition of the state of charge and the driving information.

By watching the log screen 83, the user can confirm the fluctuation in state of charge of the in-vehicle battery 41, and the use of the EV 4 that has caused the fluctuation. For example, the user can readily confirm by watching the log screen 83 that “travel to Hakone” caused the decrease in state of charge from 70% to 10% on January 4.

As described above, the server 2 includes, as separate tables, the battery information management table 26B for managing the battery information such as the state of charge, and the driving information management table 26C for managing the driving information. This makes it possible to separately manage the battery information indicating information of the in-vehicle battery, and the driving information of each user. Accordingly, while the battery information is provided to an in-vehicle battery manufacturer, automobile manufacturer, or the like, the driving information pertaining to the privacy of the user is used within a predetermined range (e.g., the user and his or her family). This facilitates controlling access to each information items. Therefore, the in-vehicle battery manufacturer, automobile manufacturer, or the like can maintain and improve the in-vehicle battery by using the provided battery information, and a leak of the driving information concerning the privacy of the user can be avoided.

Note that the battery information management table 26B and driving information management table 26C may also be stored in the client terminal 1. In this case, the log screen 83 is displayed by using the locally managed battery information and driving information, and the user can readily confirm the cause of the fluctuation in power consumption by the EV 4.

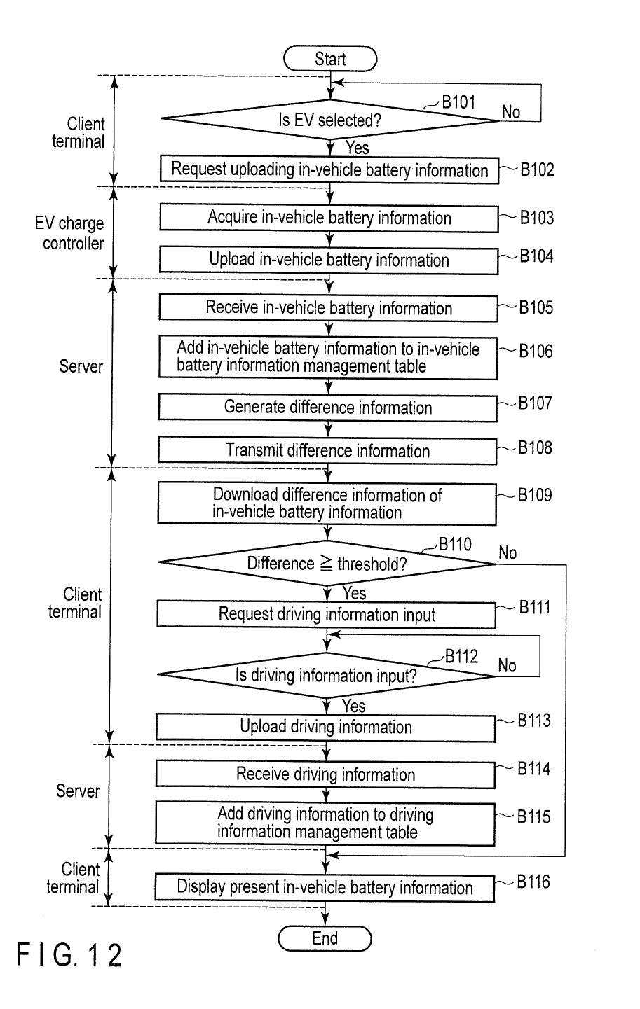

Next, with reference to a flowchart shown in FIG. 12, an example of the procedure of a power consumption management process to be executed by the power consumption management system of this embodiment will be explained. In this power consumption management process, battery information 4B is uploaded from the electric vehicle (EV) 4 to the server 2, and driving information corresponding to the battery information 4B is uploaded from the client terminal 1 to the server 2.

First, the apparatus selector 62 determines whether the EV 4 is selected as a management target apparatus (block B101). The apparatus selector 62 detects whether the EV 4 is selected from, e.g., the list of various consumer apparatuses (e.g., the EV, a refrigerator, and an air conditioner) displayed by the apparatus list display processor 61.

If the EV 4 is not selected as a management target apparatus (NO in block B101), the process returns to block B101, and whether the EV 4 is selected as a management target apparatus is determined again.

If the EV 4 is selected as a management target apparatus (YES in block B101), the apparatus selector 62 requests the EV charge controller 51 to upload the battery information 4B of the EV 4 to the server 2 (block B102).

When the request detector 55 of the EV charge controller 51 detects this request for acquiring the battery information 4B, the battery information acquisition module 56 acquires the battery ID 4A and battery information 4B from the EV 4 (block B103). Then, the battery information transmitter 57 transmits (i.e., uploads) the acquired battery ID 4A and battery information 4B to the server 2 (block B104).

The battery information receiver 22 of the server 2 receives the battery ID 4A and battery information 4B transmitted from the EV charge controller 51 (the battery information transmitter 57) (block B105). Then, the battery information receiver 22 adds a pair of the received battery ID 4A and battery information 4B to the battery information management table 26B (block B106). More specifically, the battery information receiver 22 generates an entry including the date (or date and time) of reception, the battery ID 4A, the maximum battery capacity and present residual battery capacity of the in-vehicle battery 41 included in the battery information 4B, and the state of charge of the in-vehicle battery 41, and then adds the generated entry to the battery information management table 26B. Note that it is also possible to use the date and state of charge included in the battery information 4B.

Subsequently, the difference information transmitter 23 generates difference information indicative of the difference between a first state of charge based on the received battery information (first information) 4B of the in-vehicle battery 41, and a second state of charge based on the battery information (second information) 4B of the in-vehicle battery 41 which is received last time (block B107). More specifically, among entries included in the battery information management table 26B and including the same battery ID as the battery ID associated with the first information, the difference information transmitter 23 reads an entry including the second latest date (i.e., an entry including the second information received last time). Then, the difference information transmitter 23 calculates a difference (second state of charge—first state of charge) by subtracting the first state of charge based on the first information from the second state of charge included in the read entry. The difference information transmitter 23 transmits difference information including the calculated difference of state of charge to the client terminal 1 (block B108).

The difference information receiver 63 of the client terminal 1 receives (downloads) the difference information transmitted from the server 2 (the difference information transmitter 23) (block B109). Then, the difference information receiver 63 determines whether the difference of state of charge included in the difference information is equal to or larger than the threshold (block B110).

If the difference of state of charge is smaller than the threshold (NO in block B110), the battery information display processor 67 of the client terminal 1 displays the battery information screen 82 showing the current information of the in-vehicle battery 41 (block B116).

On the other hand, if the difference of state of charge is equal to or larger than the threshold (YES in block B110), the driving information input screen display processor 64 displays the driving information input screen 81 for inputting the driving information, and prompts the user to input the driving information (block B111). Then, the driving information input processor 65 determines whether the driving information is input (block B112). If no driving information is input (NO in block B112), the process returns to block B112, and whether the driving information is input is determined again. If the driving information is input (YES in block B112), the driving information transmitter 66 transmits (uploads) the user ID 106A and driving information to the server 2 (block B113).

The driving information receiver 24 of the server 2 receives the user ID 106A and driving information transmitted from the client terminal 1 (the driving information transmitter 66) (block B114). Then, the driving information receiver 24 adds the received driving information to the driving information management table 26C (block B115). More specifically, the driving information receiver 24 generates an entry including the date (or date and time) of reception, the user ID 106A, and the driving information, and then adds the generated entry to the driving information management table 26C. Also, the battery information display processor 67 of the client terminal 1 displays the driving information screen 82 showing the current information of the in-vehicle battery 41 (block B116). Note that the display of the battery information screen 82 in block B116 may also be executed, after the driving information is input, in parallel with the upload of the user ID 106A and driving information in block B113.

By the above processing, the battery information 4B and driving information can be saved in the server 2.

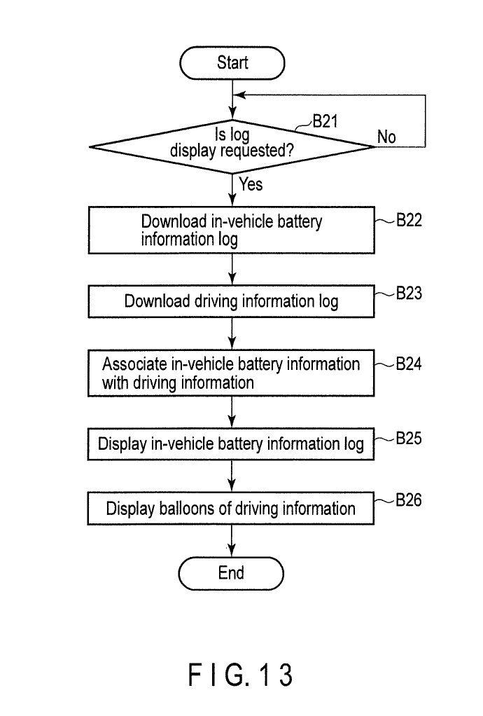

An example of the procedure of a log display process to be executed by the client terminal 1 will now be explained with reference to a flowchart shown in FIG. 13.

First, the log requesting module 68 determines whether it is requested to display the log of the power consumption by the EV 4 (block B21). The log requesting module 68 determines that the display of the log is requested when, e.g., the log button 823 on the battery display screen 82 is selected (tapped). If the display of the log is not requested (NO in block B21), the process returns to block B21, and whether the display of the log is requested is determined again.

If the display of the log is requested (YES in block B21), the log requesting module 68 transmits the battery ID 4A (i.e., the battery ID 4A of the in-vehicle battery 41 of the EV 4) stored in the nonvolatile memory 106 to the server 2, and receives (downloads) the battery information including the battery ID 4A from the battery information management table 26B stored in the server 2 (block B22). Then, the log requesting module 68 transmits the user ID 106A stored in the nonvolatile memory 106 to the server 2, and receives (downloads) the driving information including the user ID 106A from the driving information management table 26C stored in the server 2 (block B23). Note that the log requesting module 68 may also transmit either the battery ID 4A or the user ID 106A, and download the corresponding battery information and driving information. Since the server 2 stores the ID management table 26A indicative of the correspondence between the battery ID 4A and user ID 106A, it is possible to detect the user ID 106A corresponding to the battery ID 4A, or the battery ID 4A corresponding to the user ID 106A, by referring to the ID management table 26A. By transmitting one of the two IDs, therefore, it is possible to download the battery information including the battery ID 4A and the driving information including the user ID 106A from the server 2. To prevent a leak of the privacy of the user, however, the server 2 preferably transmits the driving information corresponding to the user ID 106A only when receiving the user ID 106A.

Subsequently, the log display processor 70 associates the received battery information with the driving information (block B24). That is, the log display processor 70 generates the log table 70A by integrating the battery information and driving information, based on the date in each entry of the battery information and the date in each entry of the driving information.

By using the generated log table 70A, the log display processor 70 displays the log screen 83 including the graph (e.g., a line graph) 831 indicative of the relationship between the date and state of charge (block B25). In addition, the log display processor 70 displays, by using the log table 70A, pieces of driving information 832, 833, and 834 as balloons for the graph 831 (block B26).

Since the state of charge of the in-vehicle battery 41 and the driving information are displayed in association with each other by the above processing, the user can readily confirm the cause of the fluctuation in power consumption by the electric vehicle.

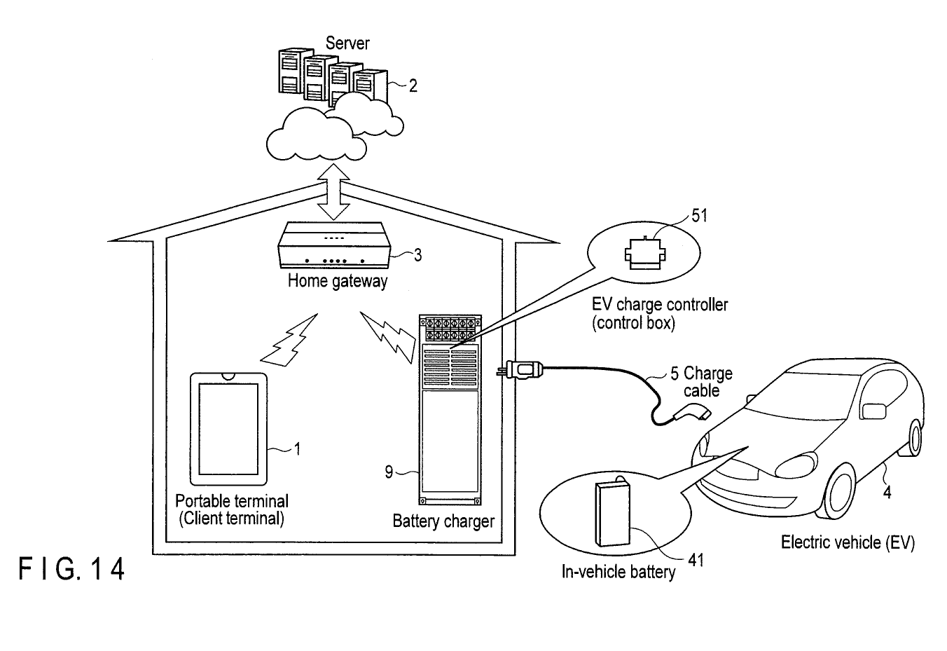

Note that as shown in FIG. 14, the EV charge controller 51 of this embodiment may also be installed in a charger 9, instead of being attached to the charge cable 5. The charger 9 is, e.g., a household EV charger for controlling charging of the EV 4. The charger 9 and EV 4 are connected by the charge cable 5. Accordingly, the in-vehicle battery 41 of the EV 4 is charged by using electric power supplied by the charger 9 through the charge cable 5. Also, the EV charge controller 51 communicates with the EV 4 through the charge cable 5. The operations of the client terminal 1, server 2, home gateway 3, and EV charge controller 51 are as described above.

In this embodiment as has been explained above, the user can readily confirm the cause of the fluctuation in power consumption by an electric vehicle. The fluctuation in power consumption by the EV 4 is represented by, e.g., the fluctuation in state of charge of the in-vehicle battery 41 of the EV 4. Also, the cause of the fluctuation in power consumption (state of charge) is represented by the driving information indicating the use of the EV 4 when the fluctuation occurred. As this driving information, the user can easily set a description readily recognizable by the user, by voice input using the microphone 18, or by character input using the keyboard (software keyboard). The client terminal 1 displays the log screen 83 showing the fluctuation in state of charge within a predetermined period and the driving information which is laid out in association with the state of charge. This enables the user to readily grasp the cause of the fluctuation in power consumption by the EV 4.

All the process procedures in this embodiment, which have been described with reference to the flowcharts of FIGS. 12 and 13, can be executed by software. Thus, the same advantageous effects as with the present embodiment can easily be obtained simply by installing a computer program, which executes the process procedures, into an ordinary computer through a computer-readable storage medium which stores the computer program, and by executing the computer program.

The various modules of the systems described herein can be implemented as software applications, hardware and/or software modules, or components on one or more computers, such as servers. While the various modules are illustrated separately, they may share some or all of the same underlying logic or code.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An electronic apparatus comprising:
a difference information receiver configured to receive difference information indicative of a difference between a first state of charge of a battery in an electric vehicle and a second state of charge of the battery from a server, the difference being obtained based on first information for the first state and second information for the second state, the first information being uploaded from the electric vehicle, the second information being uploaded immediately before the first information from the electric vehicle;
an input processor configured to receive, if the difference information indicates that a decrease in state of charge is equal to or larger than a threshold, an input comprising a use of the electric vehicle from a timing at which the second information is uploaded to a timing at which the first information is uploaded;
a driving information transmitter configured to transmit driving information to the server, the driving information being generated based on the input;
a log receiver configured to receive a plurality of battery information items and one or more driving information items from the server, the battery information items comprising the first information and the second information, the one or more driving information items comprising the transmitted driving information; and
a log display processor configured to display a log screen comprising states of charge of the battery based on the battery information items, and the one or more driving information items laid out in association with the states of charge.

2. The apparatus of claim 1, wherein the log screen comprises a graph indicative of a transition of the states of charge, and the one or more driving information items laid out in association with the graph.

3. The apparatus of claim 1, wherein the difference information receiver is configured to receive the difference information when the first information is uploaded to the server.

4. The apparatus of claim 1, wherein the server is configured to store a battery information management table comprising the battery information items, and a driving information management table comprising the one or more driving information items.

5. The apparatus of claim 1, further comprising an input screen display processor configured to display a driving information input screen for inputting the driving information, if the difference information indicates that the decrease in state of charge is equal to or larger than the threshold,
wherein the input processor is configured to receive the input on the driving information input screen by using a keyboard.

6. The apparatus of claim 1, further comprising an input screen display processor configured to display a driving information input screen for inputting the driving information, if the difference information indicates that the decrease in state of charge is equal to or larger than the threshold,
wherein the input processor is configured to receive the input on a microphone while the driving information input screen is displayed.

7. A power consumption display method comprising:
receiving difference information indicative of a difference between a first state of charge of a battery in an electric vehicle and a second state of charge of the battery from a server, the difference being obtained based on first information for the first state and second information for the second state, the first information being uploaded from the electric vehicle, the second information being uploaded immediately before the first information from the electric vehicle;
receiving, if the difference information indicates that a decrease in state of charge is equal to or larger than a threshold, an input comprising a use of the electric vehicle from a timing at which the second information is uploaded to a timing at which the first information is uploaded;
transmitting driving information to the server, the driving information being generated based on the input;
receiving a plurality of battery information items and one or more driving information items from the server, the battery information items comprising the first information and the second information, the one or more driving information items comprising the transmitted driving information; and
displaying a log screen comprising states of charge of the battery based on the battery information items, and the one or more driving information items laid out in association with the states of charge.

8. The method of claim 7, wherein the log screen comprises a graph indicative of a transition of the states of charge, and the one or more driving information items laid out in association with the graph.

9. A computer-readable, non-transitory storage medium having stored thereon a program which is executable by a computer, the program controlling the computer to execute functions of:
receiving difference information indicative of a difference between a first state of charge of a battery in an electric vehicle and a second state of charge of the battery from a server, the difference being obtained based on first information for the first state and second information for the second state, the first information being uploaded from the electric vehicle, the second information being uploaded immediately before the first information from the electric vehicle;
receiving, if the difference information indicates that a decrease in state of charge is equal to or larger than a threshold, an input comprising a use of the electric vehicle from a timing at which the second information is uploaded to a timing at which the first information is uploaded;
transmitting driving information to the server, the driving information being generated based on the input;
receiving a plurality of battery information items and one or more driving information items from the server, the battery information items comprising the first information and the second information, the one or more driving information items comprising the transmitted driving information; and
displaying a log screen comprising states of charge of the battery based on the battery information items, and the one or more driving information items laid out in association with the states of charge.

10. The computer-readable, non-transitory storage medium of claim 9, wherein the log screen comprises a graph indicative of a transition of the states of charge, and the one or more driving information items laid out in association with the graph.
